(19) United States
(12) Patent Application Publication
(10) Pub. No.: US 2006/0019438 A1
(43) Pub. Date: Jan. 26, 2006

(54) Semiconductor device and method of manufacturing the same

(76) Inventor: Hideaki Harakawa, Kawasaki-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/187,967

(22) Filed: Jul. 25, 2005

(30) Foreign Application Priority Data
Jul. 26, 2004 (JP) 2004-217561

(51) Int. Cl. H01L 21/8238

(52) U.S. Cl. 438/199; 438/230; 438/231

(57) ABSTRACT

A semiconductor device is disclosed, which includes an n-channel MISFET including a first gate electrode and a first spacer formed on a side surface of the first gate electrode, the first spacer having a compressive stress; and a p-channel MISFET comprising a second gate electrode and a second spacer formed on a side surface of the second gate electrode, the second spacer having a compressive stress, wherein the compressive stress of the second spacer is smaller than the compressive stress of the first spacer.

### CROSS-REFERENCE TO RELATED APPLICATIONS

This application is based upon and claims the benefit of priority from prior Japanese Patent Application No. 2004-217561, filed Jul. 26, 2004, the entire contents of which are incorporated herein by reference.

### BACKGROUND OF THE INVENTION

1. Field of the Invention

The present invention relates to a semiconductor device having CMISFET (Complementary Metal-Insulator-Semiconductor Field Effect Transistor) and a method of manufacturing the same, and more particularly to a semiconductor device in which stress is applied to an channel region of CMISFET and a method of manufacturing the same.

2. Description of the Related Art

As a measure for improving drive current in a CMIS circuit, application of stress to silicon of a channel region of MISFET has been well known.

As a measure for improving drive current of a MISFET, a method of depositing a silicon nitride film on a gate electrode of the MISFET and applying stress to a channel region of the MISFET has been well known (Jpn. Pat. Appln. KOKAI Publication No. 2003-179157). However although this method is effective for the n-channel MISFET whose carrier is electron, this method has a problem that the mobility is deteriorated in the p-channel MISFET whose carrier is hole, thereby drive current drops.

To improve the drive current of the CMIS circuit, improvement of the carrier mobility of the p-channel MISFET and n-channel MISFET has been required.

### BRIEF SUMMARY OF THE INVENTION

According to an aspect of the present invention, there is provided a semiconductor device comprising:

an n-channel MISFET including a first gate electrode and a first spacer formed on a side surface of the first gate electrode, the first spacer having a compressive stress; and

a p-channel MISFET comprising a second gate electrode and a second spacer formed on a side surface of the second gate electrode, the second spacer having a compressive stress, wherein

the compressive stress of the second spacer is smaller than the compressive stress of the first spacer.

According to another aspect of the present invention, there is provided a method of manufacturing a semiconductor device, comprising:

forming a gate electrode on a gate insulating film formed on a p-type semiconductor layer and a gate electrode on a gate insulating film formed on an n-type semiconductor layer;

forming a first spacer having a compressive stress on a side surface of the gate electrode formed on the p-type semiconductor layer; and

forming a second spacer having a compressive stress on a side surface of the gate electrode formed on the n-type semiconductor layer, the compressive stress of the second spacer being smaller than the compressive stress of the first spacer.

According to a further aspect of the present invention, there is provided a method of manufacturing a semiconductor device, comprising:

forming a gate electrode on a gate insulating film formed on a p-type semiconductor layer and a gate electrode on a gate insulating film formed on an n-type semiconductor layer;

forming a first spacer having a compressive stress on side surfaces of the gate electrodes formed on the p-type and n-type semiconductor layers;

removing the first spacer on the side surface of the gate electrode formed on the n-type semiconductor layer;

forming a second spacer having a compressive stress on the side surface of the gate electrode formed on the n-type semiconductor layer and a side surface of the first spacer on the side surface of the gate electrode formed on the p-type semiconductor layer, the compressive stress of the second spacer being smaller than the compressive stress of the first spacer; and, removing the second spacer formed on the side surface of the first spacer on the side surface of the gate electrode formed on the p-type semiconductor layer.

### BRIEF DESCRIPTION OF THE SEVERAL VIEWS OF THE DRAWING

FIG. 1 is a sectional view of a device structure in a step of a semiconductor device manufacturing method according to an embodiment of the present invention;

FIG. 2 is a sectional view of a device structure in a step subsequent to the step of FIG. 1, of the semiconductor device manufacturing method according to the embodiment of the invention;

FIG. 3 is a sectional view of a device structure in a step subsequent to the step of FIG. 2, of the semiconductor device manufacturing method according to the embodiment of the invention;

FIG. 4 is a sectional view of a device structure in a step subsequent to the step of FIG. 3, of the semiconductor device manufacturing method according to the embodiment of the invention;

FIG. 5 is a sectional view of a device structure in a step subsequent to the step of FIG. 4, of the semiconductor device manufacturing method according to the embodiment of the invention; and

FIG. 6 is a sectional view of a device structure in a step subsequent to the step of FIG. 5, of the semiconductor device manufacturing method according to the embodiment of the invention.

### DETAILED DESCRIPTION OF THE INVENTION

A semiconductor device and a method of manufacturing the semiconductor device according to the embodiment of the present invention will be described with reference to the accompanying drawings.

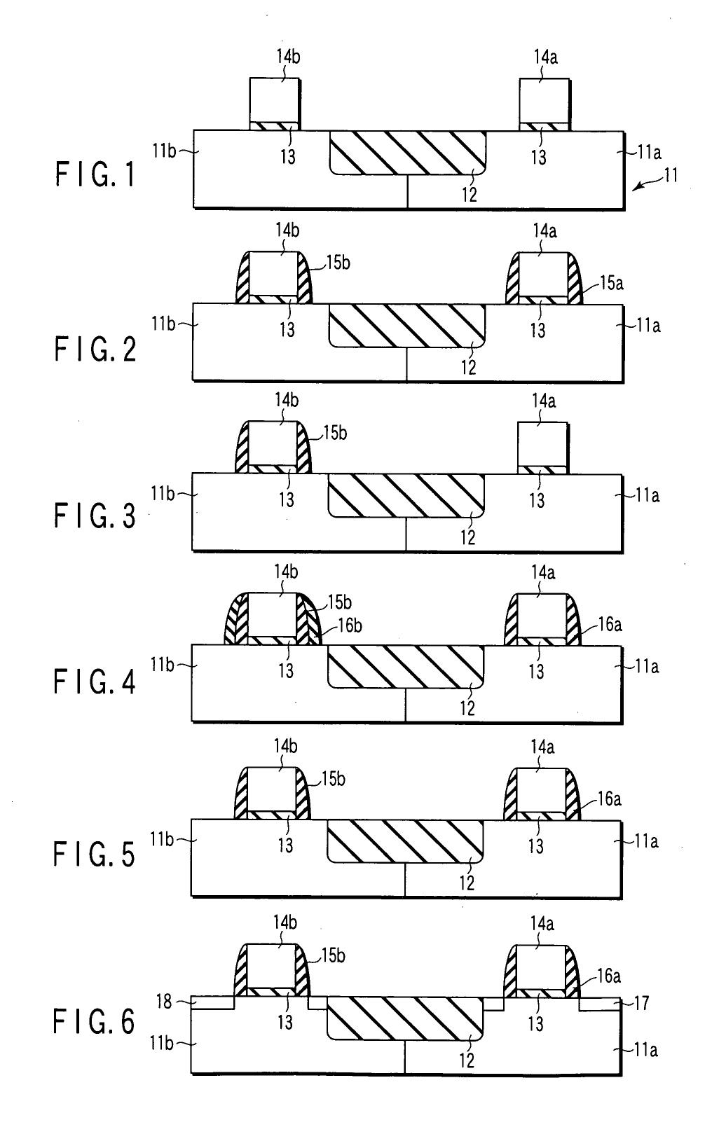

First, as shown in FIG. 1, a silicon oxide film is selectively embedded in a silicon substrate 11 to from a device separation insulating film 12. A gate insulating film 13 composed of SiO₂ is deposited on the silicon substrate 11. The gate insulating film 13 may be a film composed of other insulation material than SiO₂. By ion implantation and annealing, an n-type silicon layer 11a in which a p-channel MISFET is formed at later steps and a p-type silicon layer 11b in which an n-channel MISFET is formed at later steps are formed in the silicon substrate 11. A polycrystalline silicon film is deposited on the gate insulating film 13 by using LPCVD (Low Pressure Chemical Vapor Deposition) technology. A resist pattern, not shown, is formed on the polycrystal silicon film by using lithography technology. By dry etching technology with the resist pattern used as a mask, the polycrystalline silicon film is etched to form a gate electrode (second gate electrode) 14a on the n-type silicon layer 11a and a gate electrode (first gate electrode) 14b on the p-type silicon layer 11b. Then, the resist pattern is removed. Further, an oxide film, not shown, is formed in oxidative atmosphere.

Next, by ion implantation technology, BF₂ is implanted into the n-type silicon layer 11a and the gate electrode 14a in the order of 10¹⁴ cm⁻², and As is implanted into the p-type silicon layer 11b and the gate electrode 14b in the order of 10¹⁴ cm⁻². Then, annealing is carried out in non-oxidative atmosphere.

Next, as shown in FIG. 2, first spacers 15a and 15b of silicon nitride film are formed on side walls of the gate electrodes 14a and 14b. The first spacers 15a and 15b are formed by depositing a silicon nitride film on the silicon substrate by use of LPCVD technology, and then etching back the deposited silicon nitride film by use of dry etching technology. When the silicon nitride film is formed, an impurity concentration of the silicon nitride film may be controlled to change the stress of the silicon nitride film.

Next, as shown in FIG. 3, by removing the first spacer 15a formed on the side wall of the gate electrode 14a on the n-type silicon layer 11a, to thereby expose the side wall of the gate electrode 14a. To remove the first spacer 15a, a resist pattern covering the gate electrode 14b and the first spacer 15b is formed over the p-type silicon layer 11b by lithography technology, and the first spacer 15a formed on the gate electrode 14a is removed with this resist pattern used as a mask, by using wet etching technology. After the removing of the first spacer 15a, the resist pattern is removed.

Next, as shown in FIG. 4, second spacers 16b and 16a of silicon oxide are formed on the side wall of the first spacer 15b on the p-type silicon layer 11b and on the side wall of the gate electrode 14a on the n-type silicon layer 11a. To form the second spacers 16b and 16a, a silicon oxide film is deposited over the silicon substrate by using LPCVD technology, and then the deposited silicon oxide film is etch-backed by use of the dry etching technology. As a result, a laminated film of the first spacer 15b and second spacer 16b is formed on the side wall of the gate electrode 14b on the p-type silicon layer 11b, and at the same time, the second spacer 16a is formed on the side wall of the gate electrode 14a on the n-type silicon layer 11a. Compression stress of the silicon oxide film forming the second spacer is smaller than that of the silicon nitride film forming the first spacer.

Next, as shown in FIG. 5, the second spacer 16b formed on the side wall of the first spacer 15b on the p-type silicon layer 11b is removed. To remove the second spacer 16b, a resist pattern covering the gate electrode 14a and the second spacer 16a is formed over the n-type silicon layer 11a by using lithography technology, and then using this resist pattern as a mask, the second spacer 16b is removed by supplying a solution for etching the silicon oxide film to the substrate. Then, the resist pattern is removed.

Subsequently, a resist pattern, not shown, covering the gate electrode 14b and the first spacer 15b is formed over the p-type silicon layer 11b by using lithography technology, and then using the resist pattern as a mask, P is implanted into the n-type silicon layer 11a in the order of 10¹⁵ cm⁻² by ion implantation technology to thereby form P⁺ diffusion regions 17 used as source/drain regions in the n-type silicon layer 11a, as shown in FIG. 6. Thereafter, the resist pattern is removed. Similarly, a resist pattern, not shown, covering the gate electrode 14a and the second spacer 16a is formed over the n-type silicon layer 11a by using lithography technology, and then using the resist pattern as a mask, B is implanted into the p-type silicon layer 11b in the order of 10¹⁵ cm⁻² by ion implantation technology to thereby form n⁺ diffusion regions 18 used as source/drain regions in the p-type silicon layer 11b. Thereafter, the resist pattern is removed.

According to the described embodiment, as means for applying stress to the channel region of the MISFET, a stress of the side wall film material of the gate electrode is utilized. Thus, it is possible to avoid an over-etching at forming contacts to the source and drain regions. In a conventional dual stress liner technique, a contact liner film having a tensile stress is formed on the n-channel MISFET region and a contact liner film having a compressive stress is formed on the p-channel MISFET region. The contact liners are superposed on the border between the n-channel and p-channel MISFET regions, and thus the thickness of the contact liners is twice that of the non-superposed region. Hence, it is required to carry out an over-etching when forming contacts to the source and drain regions. At the etching, the silicide layers are also subject to etching to degrade the junction leakage characteristics.

Also, according to the described embodiment, a silicon nitride film is used as the side wall film of the gate electrode of the n-channel MISFET, and a silicon oxide film is used as the side wall film of the gate electrode of the p-channel MISFET. Compression stress of silicon oxide is smaller than that of silicon nitride. As a consequence, the performance of the n-channel MISFET can be improved without deteriorating the performance of p-channel MISFET.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
an n-channel MISFET including a first gate electrode and a first spacer formed on a side surface of the first gate electrode, the first spacer having a compressive stress; and
a p-channel MISFET comprising a second gate electrode and a second spacer formed on a side surface of the second gate electrode, the second spacer having a compressive stress, wherein
the compressive stress of the second spacer is smaller than the compressive stress of the first spacer.

2. The semiconductor device according to claim 1, wherein a material of the first spacer is silicon nitride.

3. The semiconductor device according to claim 1, wherein a material of the second spacer is silicon oxide.

4. The semiconductor device according to claim 1, wherein a material of the first spacer is silicon nitride, and a material of the second spacer is silicon oxide.

5. A method of manufacturing a semiconductor device, comprising:
forming a gate electrode on a gate insulating film formed on a p-type semiconductor layer and a gate electrode on a gate insulating film formed on an n-type semiconductor layer;
forming a first spacer having a compressive stress on a side surface of the gate electrode formed on the p-type semiconductor layer; and
forming a second spacer having a compressive stress on a side surface of the gate electrode formed on the n-type semiconductor layer, the compressive stress of the second spacer being smaller than the compressive stress of the first spacer.

6. The method of manufacturing a semiconductor device, according to claim 5, wherein a silicon nitride film is formed as the first spacer.

7. The method of manufacturing a semiconductor device, according to claim 6, wherein an impurity concentration of the silicon nitride film is controlled when the silicon nitride film is formed as the first spacer.

8. The method of manufacturing a semiconductor device, according to claim 5, wherein a silicon oxide film is formed as the second spacer.

9. The method of manufacturing a semiconductor device, according to claim 5, wherein a silicon nitride film is formed as the first spacer, and a silicon oxide film is formed as the second spacer.

10. The method of manufacturing a semiconductor device, according to claim 5, further comprising implanting p-type impurities into the n-type semiconductor layer to form p-type source/drain regions in the n-type semiconductor layer, and implanting n-type impurities into the p-type semiconductor layer to form n-type source/drain regions in the p-type semiconductor layer, these implanting of the p-type impurities and the n-type impurities being carried out after the gate electrodes and the first and second spacers are formed.

11. A method of manufacturing a semiconductor device, comprising:
forming a gate electrode on a gate insulating film formed on a p-type semiconductor layer and a gate electrode on a gate insulating film formed on an n-type semiconductor layer;
forming a first spacer having a compressive stress on side surfaces of the gate electrodes formed on the p-type and n-type semiconductor layers;
removing the first spacer on the side surface of the gate electrode formed on the n-type semiconductor layer;
forming a second spacer having a compressive stress on the side surface of the gate electrode formed on the n-type semiconductor layer and a side surface of the first spacer on the side surface of the gate electrode formed on the p-type semiconductor layer, the compressive stress of the second spacer being smaller than the compressive stress of the first spacer; and,
removing the second spacer formed on the side surface of the first spacer on the side surface of the gate electrode formed on the p-type semiconductor layer.

12. The method of manufacturing a semiconductor device, according to claim 11, wherein a silicon nitride film is formed as the first spacer.

13. The method of manufacturing a semiconductor device, according to claim 12, wherein an impurity concentration of the silicon nitride film is controlled when the silicon nitride film is formed as the first spacer.

14. The method of manufacturing a semiconductor device, according to claim 11, wherein a silicon oxide film is formed as the second spacer.

15. The method of manufacturing a semiconductor device, according to claim 11, wherein a silicon nitride film is formed as the first spacer, and a silicon oxide film is formed as the second spacer.

16. The method of manufacturing a semiconductor device, according to claim 15, wherein the removing of the first spacer on the side surface of the gate electrode formed on the n-type semiconductor layer is carried out by forming a resist pattern covering the gate electrode formed on the p-type semiconductor layer and the first spacer on the side surface of the gate electrode formed on the p-type semiconductor layer, and removing the first spacer on the side surface of the gate electrode formed on the n-type semiconductor layer.

17. The method of manufacturing a semiconductor device, according to claim 11, further comprising implanting p-type impurities into the n-type semiconductor layer to form p-type source/drain regions in the n-type semiconductor layer, and implanting n-type impurities into the p-type semiconductor layer to form n-type source/drain regions in the p-type semiconductor layer, these implanting of the p-type impurities and the n-type impurities being carried out after the gate electrodes and the first and second spacers are formed.
